(19) United States
(12) Patent Application Publication
(10) Pub. No.: US 2022/0148201 A1
(43) Pub. Date: May 12, 2022

(54) WAFER ALIGNMENT METHOD AND APPARATUS

(71) Applicant: CHANGXIN MEMORY TECHNOLOGIES, INC., Hefei City (CN)

(72) Inventor: Ning HUANG, Hefei City (CN)

(73) Assignee: CHANGXIN MEMORY TECHNOLOGIES, INC., Hefei City (CN)

(21) Appl. No.: 17/648,677

(22) Filed: Jan. 23, 2022

Related U.S. Application Data
(63) Continuation of application No. PCT/CN2021/104345, filed on Jul. 2, 2021.

(30) Foreign Application Priority Data
Sep. 18, 2020 (CN) 202010986868.9

(51) Int. Cl. G06T 7/33; G06T 7/00; G06T 7/73; G06T 3/40; H01L 21/68

(52) U.S. Cl. CPC G06T 7/337; G06T 7/001; G06T 2207/30148; G06T 3/40; H01L 21/681; G06T 7/73

(57) ABSTRACT

A wafer alignment method includes: obtaining a wafer image of a wafer to be aligned; extracting a plurality of feature images from the wafer image; matching the plurality of feature images with a preset image; and aligning the wafer to be aligned according to the matching result. During wafer alignment, by matching feature images extracted from a wafer image with a preset image and aligning a wafer to be aligned according to the matching result, matching granularity is refined, and a success rate of the wafer alignment is improved.

### CROSS-REFERENCE TO RELATED APPLICATIONS

This is a continuation of International Application No. PCT/CN2021/104345 filed on Jul. 2, 2021, which claims priority to Chinese Patent Application No. 202010986868.9 filed on Sep. 18, 2020. The disclosures of the above-referenced applications are hereby incorporated by reference in their entirety.

### BACKGROUND

In semiconductor integrated circuit manufacturing or process inspection procedures, wafers may be subjected to a plurality of manufacturing process stages, where wafer alignment is a crucial step.

### SUMMARY

Embodiments of the present application relate to the technical field of semiconductors, and in particular, to a wafer alignment method and apparatus.

Embodiments of the present application provide a wafer alignment method and apparatus.

In a first aspect, the embodiments of the present application provide a wafer alignment method. The wafer alignment method includes:

obtaining a wafer image of a wafer to be aligned; extracting several feature images from the wafer image; matching the feature images with a preset image; and aligning the wafer to be aligned according to the matching result.

In a second aspect, the embodiments of the present application further provide a wafer alignment apparatus. The wafer alignment apparatus includes an obtaining unit, a processing unit and an alignment unit.

The obtaining unit is configured to obtain a wafer image of a wafer to be aligned.

The processing unit is configured to extract several feature images from the wafer image and match the feature images with a preset image.

The alignment unit is configured to align the wafer to be aligned according to the matching result.

In a third aspect, the embodiments of the present application provide a wafer alignment apparatus. The wafer alignment apparatus includes a memory and a processor.

The memory is configured to store a computer program.

The processor is configured to read the computer program stored in the memory, and execute the wafer alignment method of any one of possible implementations in the first aspect according to the computer program in the memory.

### BRIEF DESCRIPTION OF THE DRAWINGS

The accompanying drawings are incorporated in and constitute a part of the description, illustrate embodiments in line with the present application and, together with the description, serve to explain the principles of the embodiments of the present application.

FIG. 1 is a schematic flowchart of a wafer alignment method according to an embodiment of the present application.

FIG. 2 is a schematic diagram of feature patterns of a wafer to be aligned according to an embodiment of the present application.

FIG. 3 is a schematic structural diagram of a wafer alignment apparatus according to an embodiment of the present application.

FIG. 4 is a schematic structural diagram of another wafer alignment apparatus according to an embodiment of the present application.

Specific embodiments of the present application have been described in the above drawings, for which more detailed descriptions will be made later. These drawings and text descriptions are not intended to limit the scope of the present application in any way, but to explain concepts of the present application to those skilled in the art with reference to the specific embodiments.

### DETAILED DESCRIPTION

Reference will be made in detail to exemplary embodiments, examples of which are illustrated in the accompanying drawings. The following description refers to the accompanying drawings in which the same numbers in different drawings represent the same or similar elements unless otherwise represented. The implementations set forth in the following description of exemplary embodiments do not represent all implementations consistent with the present application. Instead, they are merely examples of apparatuses and methods consistent with aspects related to the present application as recited in the appended claims.

In embodiments of the present application, the term “at least one” refers to one or more, and the term “a plurality of” refers to two or more. The term “and/or” describes an association relationship for describing associated objects and represents that three relationships may exist. For example, A and/or B may represent the following three cases: only A exists, both A and B exist, and only B exists, where A and B may be singular or plural. In text descriptions of the embodiments of the present application, the character “/” generally indicates an “or” relationship between the associated objects.

Certain factors, for example, a change in process parameters or instability of a device, in the manufacturing process may result in a change in wafer images, which affects an alignment effect, causing a success rate of wafer alignment to be relatively low.

Various embodiments of the present disclosure can address, during wafer alignment, how to improve the success rate of wafer alignment.

A wafer alignment method provided by the embodiments of the present application may be applied to scenes of semiconductor large-scale integrated circuit manufacturing or process inspection. In semiconductor large-scale integrated circuit manufacturing or process inspection procedures, semiconductor wafers may be subjected to a plurality of manufacturing process stages, and are processed or tested by a plurality of different devices. When a semiconductor device processes a patterned wafer, a robot may take the patterned wafer out of a cassette and sends it to an operating stage of the semiconductor device. After the robot delivers the patterned wafer to the operating stage of the semiconductor device, an alignment operation is performed on the wafer. Wafer alignment is a crucial step. Certain factors, for example, a change in process parameters or instability of a device, in the manufacturing process may result in a change in wafer images, which affects an alignment effect, so that a success rate of wafer alignment is reduced.

On the basis of the description above, in order to effectively improve the success rate of wafer alignment, the embodiments of the present application provide a wafer alignment method and apparatus. When wafer alignment is performed, a wafer image of a wafer to be aligned is first obtained, and several feature images are extracted from the wafer image. After the several feature images are obtained, the feature images are matched with a preset image. The wafer to be aligned is aligned according to the matching result.

The number of the several feature images may be set according to an actual requirement, which is not further limited in the embodiments of the present application. The preset image is a wafer image produced by using a preset wafer and used as an alignment reference. During alignment of the wafer to be aligned, the obtained wafer image of the wafer to be aligned is matched with the preset image, and alignment of the wafer to be aligned is determined according to the matching result.

In order to prevent matching of the wafer image of the wafer to be aligned from being interfered by other images, the selected preset image is unique within a peripheral preset range thereof. In an example, the preset range may be 15 um, or may be 15.2 um, or may be 14.8 um. The specific preset range may be set according to an actual requirement. In the embodiments of the present application, taking the preset range of 15 um as an example, a selected preset image is unique in a range within 15 um in the periphery thereof. Specifically, if a region of the selected preset image is rectangular, in a range of 15 um extending from the boundary of the rectangle to the outside, the preset image is unique, and no image that is identical or similar to the preset image exists. For example, if the selected preset image is a cross mark, then no identical or similar cross mark exists in a certain range in the periphery thereof. Moreover, the range of 15 um may just avoid a matching error caused by a placement error when the robot of the semiconductor device places the wafer to be aligned onto the stage. If the set range is too large, the manufacturing of the preset image may become more complex and takes more time, and a large range is unnecessary.

In the embodiments of the present application, aligning the wafer to be aligned is understood as determining a position of the wafer to be aligned. In an example, the position of the wafer to be aligned includes a geometrical relationship of the wafer to be aligned with respect to a stage for placing the wafer to be aligned, where the geometrical relationship includes at least one of an offset, a rotation angle, or a scale. It will be understood that after the wafer to be aligned is aligned according to the wafer alignment method provided by the embodiments of the present application, the aligned wafer may be further subjected to operations such as measurement and manufacturing. Concerning how to perform the operations such as measurement and manufacturing on the aligned wafer, reference may be made to existing measurement and manufacturing methods. Details are not described herein again in the embodiments of the present application.

In the embodiments of the present application, during wafer alignment, by matching the feature images extracted from the wafer image with the preset image and aligning the wafer to be aligned according to the matching result, matching granularity is refined, a probability of failure of wafer alignment is reduced, and a success rate of the wafer alignment is improved.

The wafer alignment method provided by the present application is described in detail in the following specific embodiments. It will be understood that in the embodiments of the present application, the following specific embodiments can be combined with each other, and the same or similar concepts or processes may not be described herein again in some embodiments. The wafer alignment method provided by the embodiments of the present application is described in detail by combining the drawings.

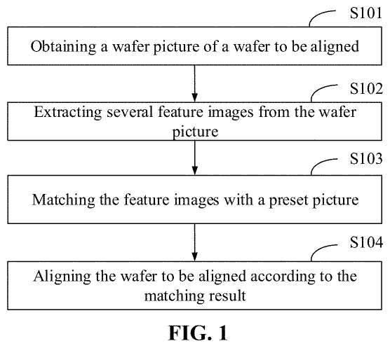

FIG. 1 is a schematic flowchart of a wafer alignment method according to an embodiment of the present application. The wafer alignment method may be executed by a software and/or hardware apparatus. For example, the hardware apparatus may be a stage for placing a wafer, or may be a control device of the stage for placing a wafer. In an example, as shown in FIG. 1, the wafer alignment method includes the following operations.

At S101, a wafer image of a wafer to be aligned is obtained.

In an example, the wafer image of the wafer to be aligned may be a black-and-white binary map, or may be a grey-scale image, or may be a color image, which may be set according to an actual requirement. Here, image types of the wafer image are not specifically limited in the embodiments of the present application.

During obtaining of the wafer image of the wafer to be aligned, one wafer image of the wafer to be aligned may be obtained on the basis of a certain position on the wafer to be aligned. For example, the number of the obtained wafer images may be one. Also, at least two wafer images of the wafer to be aligned may be obtained on the basis of at least two positions on the wafer to be aligned, and the wafer to be aligned is aligned on the basis of several feature images in the at least two wafer images. In this case, the number of the obtained wafer images may be plural.

In order to enable the obtained wafer image to better cover the entire wafer to be aligned while reducing an alignment time, wafer images of the wafer to be aligned may be respectively obtained on the basis of three positions on the wafer to be aligned.

In an example, the three positions may include a central position of the wafer to be aligned, an intermediate position of the wafer to be aligned, and an edge position of the wafer to be aligned. The wafer images of the wafer to be aligned are obtained respectively on the basis of the central position of the wafer to be aligned, the intermediate position of the wafer to be aligned, and the edge position of the wafer to be aligned. The wafer images obtained in this way may better cover the entire wafer to be aligned in a certain extent. Specifically, the central position may be any position in a region within 30% (inclusive) of a radius of the wafer. The intermediate position may be any position in a region from 30% to 40% (inclusive) of the radius of the wafer. The edge position may be any position in a region outside 70% of the radius of the wafer. Furthermore, during alignment of the wafer to be aligned on the basis of the wafer images obtained on the basis of the three positions, in order to improve the success rate of the wafer alignment, the position of the wafer to be aligned can be accurately determined by limiting arrangements of the central position of the wafer to be aligned, the intermediate position of the wafer to be aligned, and the edge position of the wafer to be aligned are limited. In an example, a triangle may be constituted by a position of the wafer image selected in the central position of the wafer to be aligned, a position of the wafer image selected in the intermediate position of the wafer to be aligned, and a position of the wafer image selected in the edge position of the wafer to be aligned.

In another example, when the wafer images of the wafer to be aligned are respectively obtained on the basis of three positions of the wafer to be aligned, the three positions may also be located in the edge positions of the wafer to be aligned, and connecting lines between the three positions constitute a triangle. Preferably, the triangle is an equilateral triangle. In such arrangement, the entire edge position of the wafer to be aligned is accurately obtained, so that determination on a position of a wafer to be aligned is more accurate, and an alignment time is reduced.

After the wafer image of the wafer to be aligned is obtained by S101 above, several feature images may be extracted from the obtained wafer image, i.e., S102 below is executed.

At S102, several feature images are extracted from the wafer image.

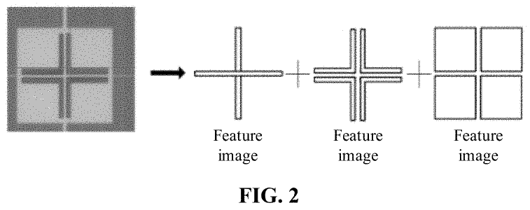

In an example, as shown in FIG. 2, FIG. 2 is a schematic diagram of feature patterns of a wafer to be aligned according to an embodiment of the present application. The obtain wafer image of the wafer to be aligned is an image of a region where a cross mark is located. The cross mark is formed by combining four L-shaped patterns which are symmetrically arranged. The extracted features images may include an overall outline of the cross mark, L-shaped outlines of the cross mark, and a rectangular region where the L-shaped patterns are located.

In an example, when the multiple features images are extracted from the obtained wafer image, the multiple features images are located in different regions of the wafer image. Specifically, feature images are respectively extracted from different regions of the wafer image, so that features in the extracted feature images are most prominent, to improve the alignment accuracy. For example, the wafer image is divided into a first region and a second region. A feature image extracted in the first region has a highest contrast ratio in the first region, and a feature image extracted in the second region has a highest contrast ratio in the second region.

In an example, it is assumed that the number of the extracted feature images is N, where N is greater than or equal to 2, the regions where at least two feature images in the N feature images are located in the wafer image overlap. Therefore, the range of the obtained wafer image may be reduced to increase an alignment speed. Furthermore, in the N feature images extracted from the obtained wafer image, and the N^{th} feature images may include the (N−1)^{th} feature image.

When the several feature images are extracted from the wafer image, no matter for the case where one wafer image of the wafer to be aligned is obtained on the basis of a certain position on the wafer to be aligned, or for the case where at least two wafer images of the wafer to be aligned are obtained on the basis of at least two positions on the wafer to be aligned, the several feature images can be extracted from the wafer image by using the implementation above. After the several feature images are extracted from the wafer image, the feature images are matched with the preset image, i.e., S103 below is executed.

At S103, the feature images are matched with a preset image.

It will be understood that before the feature images are matched with the preset image, the preset image is required to be obtained in advance. In an example, the preset image may be obtained by photographing a preset wafer in a field of view, and the preset wafer may be a first batch of wafer used in establishment of a recipe. In another example, the preset image is updated in real time according to the wafer to be aligned. Specifically, after the alignment of the wafer to be aligned is completed, the preset image may be updated to be the obtained wafer image of the wafer to be aligned. In an actual manufacturing process of wafers, index parameters of the semiconductor device actually drift slowly over time, so that wafer images on manufactured wafers also change slowly over time. Updating the preset image in real time avoids alignment failure caused by the unrecognized wafer image due to gradual changes in a long time.

When a feature image is matched with the preset image, in order to improve accuracy of the matching result, it is firstly determined whether the feature image is a unique image in the obtained wafer image of the wafer to be aligned. If the feature image is the unique image in the wafer image, it indicates that there is no other identical or similar interference image which will interfere with the matching of the feature images of the wafer to be aligned. Therefore, the feature image may be directly matched with the preset image, so as to obtain the matching result. If the feature image is not a unique image in the wafer image, other identical or similar interference images may interfere with the matching of the feature images of the wafer to be aligned. Therefore, in order to avoid the interference by other images on the matching of the feature images of the wafer to be aligned, in an example, a size of the obtained wafer image of the wafer to be aligned can be adjusted, so that the feature image extracted from the adjusted wafer image is a unique image in the adjusted wafer image. Specifically, the feature image required to be matched is generally located in the center position of the obtained wafer image, and the interference images are located in the edge position of the obtained wafer image. By reducing the size of the obtained wafer image, the interference images are easily excluded. For example, if the region where the obtained wafer image of the wafer to be aligned is located is rectangular, the interference images may be excluded from the adjusted wafer image by reducing the size of the rectangular region.

In an example, multiple preset feature images in the preset image may be extracted, and the preset feature images have one-to-one correspondence to the feature images in the wafer image of the wafer to be aligned. Specifically, the number of the preset feature images is identical to that of the feature images in the wafer image of the wafer to be aligned, and the preset feature images are identical to the feature images in the wafer image of the wafer to be aligned. In this way, when the feature images in the wafer image of the wafer to be aligned are respectively matched with the corresponding preset feature images in the preset image, matching quality may be enhanced, and matching efficiency may be improved. In combination with FIG. 2, each of the three feature images as shown in FIG. 2 may be matched with a corresponding preset feature image in the preset image in one-to-one correspondence, and thus the wafer to be aligned is aligned according to the matching result.

At S104, the wafer to be aligned is aligned according to the matching result.

In an example, when the wafer to be aligned is aligned according to the matching result, according to the matching result, for example, a matching degree score, each feature image in the several feature images is respectively matched with the preset image to determine a feature image having a highest matching degree with the preset image. After the feature image having the highest matching degree with the preset image is determined, the wafer to be aligned is aligned according to the feature image having the highest matching degree, which improves alignment precision, and then the position of the wafer to be aligned is determined. In an example, the position of the wafer to be aligned includes a geometrical relationship of the wafer to be aligned with respect to a stage for placing the wafer to be aligned, where the geometrical relationship includes at least one of an offset, a rotation angle, or a scale. In another example, in order to save alignment time and improve the alignment efficiency to increase production capacity, a matching degree score threshold may also be provided. The wafer to be aligned may be accurately aligned according to a feature image of which the matching degree exceeds the matching degree score threshold. When a matching degree between a feature image and the preset image reaches the matching degree score threshold, the wafer to be aligned is aligned by using the feature image, and matching of the remaining feature images is stopped. That is, there is no need to execute a matching operation on the remaining feature images, so that the alignment time is saved, the alignment efficiency is improved, and the production capacity is increased.

In an example, a plurality of wafer images are obtained from a wafer to be aligned, and several feature images extracted from each of the wafer images are matched with a preset image. For example, when three wafer images of the wafer to be aligned are respectively obtained from three positions on the wafer to be aligned, feature images in each of the wafer images respectively obtained from the three positions are required to be matched with the preset image, respectively, to determine a feature image having a highest matching degree with the preset image in all wafer images, and the wafer to be aligned is aligned according to the matching result of the feature images. As shown in FIG. 2, by matching each of the three feature images as shown in FIG. 2 with a preset image, a matching degree score between each feature image and the preset image is obtained. It is assumed that a matching degree score between the first feature image and the preset image is 50, a matching degree score between the second feature image and the preset image is 90, and a matching degree score between the third feature image and the preset image is 75, it can be seen that the matching degree score between the second feature image and the preset image is the highest, which indicates that a matching degree between the second feature image and the preset image is the highest. Therefore, the wafer to be aligned is aligned according to the second feature image so as to determine a position of the wafer to be aligned.

In an example, when the number of the obtained wafer images on the wafer to be aligned is multiple, a feature image having a highest matching degree with the preset image in the first wafer image is determined. During matching of remaining wafer images, a feature image identical to the feature image having the highest matching degree with the preset image in the first wafer image may be directly extracted and matched with the preset image, so that alignment accuracy is ensured, matching time is saved, and alignment efficiency is improved.

In an example, when the number of the obtained wafer images on the wafer to be aligned is multiple, feature images extracted from different wafer images are different. Due to the quality of the process, a slight difference may be caused in structures of regions of a wafer, for example, a thickness of a film layer or a size of a pattern. The slight difference may result in differences of wafer images in different regions on the wafer. When feature images extracted from wafer images of different positions are different, a feature image having a highest matching degree is matched with the preset image, to improve alignment accuracy of wafers.

In the embodiments of the present application, during wafer alignment, by matching the feature images in the wafer image with the preset image and aligning the wafer to be aligned according to the matching result, matching granularity is refined, a probability of failure of wafer alignment is reduced, and a success rate of the wafer alignment is improved.

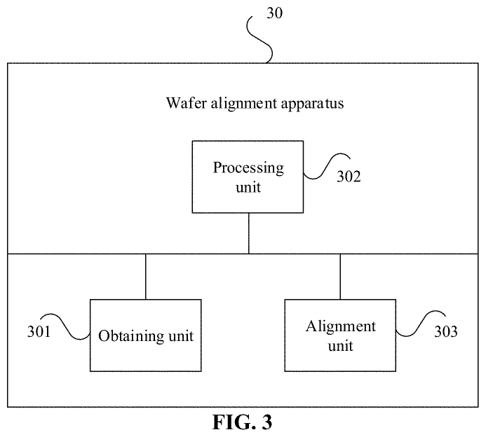

FIG. 3 is a schematic structural diagram of a wafer alignment apparatus 30 according to an embodiment of the present application. In an example, as shown in FIG. 3, the wafer alignment apparatus 30 may include:

an obtaining unit 301, configured to obtain a wafer image of a wafer to be aligned;

a processing unit 302, configured to extract several feature images in the wafer image and match the feature images with a preset image; and

an alignment unit 303, configured to align the wafer to be aligned according to the matching result.

In some embodiments, the preset image is unique within a peripheral preset range thereof.

In some embodiments, the preset image is updated according to the wafer to be aligned in real time.

In some embodiments, the alignment unit 303 is specifically configured to determine, according to a feature image having a highest matching degree, a position of the wafer to be aligned. The position of the wafer to be aligned includes a geometrical relationship of the wafer to be aligned with respect to a stage for placing the wafer to be aligned. The geometrical relationship includes at least one of an offset, a rotation angle, or a scale.

In some embodiments, the processing unit 302 is configured to determine whether a feature image is a unique image in the wafer image, and if the feature image is the unique image in the wafer image, match the feature images with a preset image.

In some embodiments, if the feature image is not the unique image in the wafer image, the processing unit 302 is further configured to adjust a size of the wafer image, so that the adjusted feature image is the unique image in the adjusted wafer image.

In some embodiments, the several feature images are located in different regions in the wafer image, respectively.

In some embodiments, the number of the feature images is N, N is greater than or equal to 2, and the N^{th} feature image includes the (N−1)^{th} feature image.

In some embodiments, the obtaining unit is specifically configured to, on the basis of at least two positions on the wafer to be aligned, respectively obtain the wafer images of the wafer to be aligned.

In some embodiments, the obtaining unit 301 is specifically configured to respectively obtain wafer images of a wafer to be aligned on the basis of three positions on the wafer to be aligned. The three positions are respectively located in a central position of the wafer to be aligned, an intermediate position of the wafer to be aligned, and an edge position of the wafer to be aligned, and connecting lines between the three positions constitute a triangle. Or, all of the three positions are located in the edge position of the wafer to be aligned, and connecting lines between the three positions constitute an equilateral triangle.

In some embodiments, the alignment unit 303 is specifically configured to match the feature images extracted from each of the wafer images with a preset image, determine the feature image having the highest matching degree in the wafer images, and according to the feature image having the highest matching degree, align the wafer to be aligned.

In some embodiments, the processing unit 302 is specifically configured to determine a feature image having a highest matching degree with the preset image in the first wafer image, and during matching of other wafer images, extract a feature image identical to the feature image, having the highest matching degree with the preset image, in the first wafer image, and match the feature image with the preset image.

In some embodiments, the feature images extracted from the different wafer images are different.

In some embodiments, the processing unit 302 is specifically configured to set a matching degree score threshold, and when a matching degree score between the feature images and the preset image reaches the matching degree score threshold, stop matching of the remaining feature images.

The wafer alignment apparatus 30 provided by the embodiments of the present application can execute the technical solution of the wafer alignment method in any one of the foregoing embodiments, and the implementation principles and beneficial effects are similar to those of the wafer alignment method. Reference may be made to the implementation principles and beneficial effects of the wafer alignment method. Details are not described herein again.

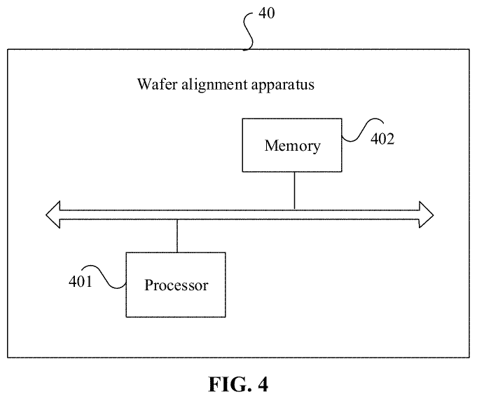

FIG. 4 is a schematic structural diagram of another wafer alignment apparatus 40 according to an embodiment of the present application. In an example, as shown in FIG. 4, the wafer alignment apparatus 40 may include a processor 401 and a memory 402.

The memory 402 is configured to store a computer program.

The processor 401 is configured to read the computer program stored in the memory 402, and execute the wafer alignment method of any one of the embodiments above according to the computer program in the memory 402.

In some embodiments, the memory 402 may be independent, or may be integrated with the processor 401. When the memory 402 is a device independent of the processor 401, the wafer alignment apparatus further includes: a bus, configured to connect the memory 402 and the processor 401.

In some embodiments, the wafer alignment apparatus 40 may further include a communication interface which may be connected to the processor 401 by means of the bus. The processor 401 controls the communication interface to implement receiving and sending functions of the wafer alignment apparatus.

The wafer alignment apparatus provided by the embodiments of the present application can execute the technical solution of the wafer alignment method in any one of the foregoing embodiments, and the implementation principles and beneficial effects are similar to those of the wafer alignment method. Reference may be made to the implementation principles and beneficial effects of the wafer alignment method. Details are not described herein again.

Embodiments of the present application further provide a computer readable storage medium. The computer readable storage medium stores computer executable instructions. when the processor executes the computer executable instructions, the technical solution of the wafer alignment method of any one of the embodiments above is realized. The implementation principles and beneficial effects thereof are similar to those of the wafer alignment method. Reference may be made to the implementation principles and beneficial effects of the wafer alignment method. Details are not described herein again.

In the several embodiments provided in the present application, it should be understood that, the disclosed system, apparatus, and method may be implemented in other manners. For example, the apparatus embodiments described above are merely exemplary. For example, the division of the units is merely the division of logic functions, and other division manners may be used during actual implementation. For example, a plurality of units or components may be combined, or may be integrated into another system, or some features may be omitted or not performed. In addition, the coupling, or direct coupling, or communication connection between the illustrated or discussed components may be the indirect coupling or communication connection by means of some interfaces, apparatuses, or units, and may be electrical or of other forms.

The units described as separate components may or may not be physically separated, and the components displayed as units may or may not be physical units, and may be located in one place or may be distributed over a plurality of network units. Some or all of the units may be selected based on actual needs to achieve the objectives of the solutions of the embodiments of the present application. In addition, functional units in the embodiments of the present application may be integrated into one processing unit, or each of the units may be physically separated, or two or more units may be integrated into one unit. The integrated units may be implemented in the form of hardware, or may be implemented in a form of hardware and software functional units.

The integrated module implemented in the form of a software functional module may be stored in a computer-readable storage medium. The software functional module is stored in a storage medium, and includes several instructions for instructing a computer device (which may be a personal computer, a server, a network device, or the like) or a processor to perform some of the steps of the methods described in the embodiments of the present application.

It should be understood that the processor may be a central processing unit (CPU), or may also be another general purpose processor, a digital signal processor (DSP), an application specific integrated circuit (ASIC), or the like. The general purpose processor may be a microprocessor or the processor may be any normal processor, or the like. The steps of the methods disclosed with reference to the invention may be directly performed by a hardware processor, or may be performed using a combination of hardware in the processor and a software module.

The memory may include a high-speed RAM memory, or may include a non-volatile memory (NVM), for example, at least one disk memory. The memory may also be a USB drive, a removable hard disk, a read-only memory (ROM), a magnetic disk, an optical disc, or the like.

The bus may be an industry standard architecture (ISA) bus, a peripheral component interconnect (PCI) bus, an extended industry standard architecture (EISA) bus, or the like. The bus may be classified into an address bus, a data bus, a control bus, or the like. For ease of representation, the bus in the accompanying drawings of the embodiments of the present application is not limited to only one bus or only one type of bus.

The computer readable storage medium may be implemented by any type of volatile or non-volatile storage device or a combination thereof, such as a static random access memory (SRAM), an electrically erasable programmable read-only memory (EEPROM), an erasable programmable read-only memory (EPROM), a programmable read-only memory (PROM), a read-only memory (ROM), a magnetic memory, a flash memory, a magnetic disk, or an optical disc. The storage medium may be any available media that can be accessed by a general purpose or special purpose computer.

It should be noted that the foregoing embodiments are merely used for describing the technical solutions of the present application, rather than limiting the present application. Although the present application is described in detail with reference to the foregoing embodiments, persons of ordinary skill in the art should understand that they can still make modifications to the technical solutions described in the foregoing embodiments or make equivalent replacements on some or all technical features therein. These modifications or replacements do not cause the essence of the corresponding technical solutions to depart from the scope of the technical solutions of the embodiments of the present application.

What is claimed is:

1. A wafer alignment method, comprising:
obtaining a wafer image of a wafer to be aligned;
extracting a plurality of feature images from the wafer image;
matching the plurality of feature images with a preset image; and
aligning the wafer to be aligned according to the matching result.

2. The method of claim 1, wherein the preset image is unique within a peripheral preset range thereof.

3. The method of claim 1, wherein the preset image is updated in real time according to the wafer to be aligned.

4. The method of claim 1, wherein the aligning the wafer to be aligned according to the matching result comprises:
determining a position of the wafer to be aligned according to a feature image having a highest matching degree, wherein the position of the wafer to be aligned comprises a geometrical relationship of the wafer to be aligned with respect to a stage for placing the wafer to be aligned, and the geometrical relationship comprises at least one of an offset, a rotation angle, or a scale.

5. The method of claim 1, wherein said matching the plurality of feature images with a preset image comprises:
determining whether a feature image is a unique image in the wafer image; and
if the feature image is the unique image in the wafer image, matching the feature image with the preset image.

6. The method of claim 5, wherein if the feature image is not the unique image in the wafer image, the method further comprises:
adjusting a size of the wafer image, so that the adjusted feature image is the unique image in the adjusted wafer image.

7. The method of claim 1, wherein the plurality of feature images are located in different regions in the wafer image, respectively.

8. The method of claim 1, wherein number of the plurality of feature images is N, N is greater than or equal to 2, and the N^{th} feature image comprises the (N−1)^{th} feature image.

9. The method of claim 1, wherein said obtaining the wafer image of the wafer to be aligned comprises:
obtaining wafer images of the wafer to be aligned respectively on the basis of at least two positions on the wafer to be aligned.

10. The method of claim 9, wherein said obtaining the wafer images of the wafer to be aligned respectively on the basis of at least two positions on the wafer to be aligned comprises:
obtaining wafer images of the wafer to be aligned respectively on the basis of three positions on the wafer to be aligned, wherein
the three positions are respectively located in a central position of the wafer to be aligned, an intermediate position of the wafer to be aligned, and an edge position of the wafer to be aligned, and connecting lines between the three positions constitute a triangle; or
all of the three positions are located in edge positions of the wafer to be aligned, and connecting lines between the three positions constitute an equilateral triangle.

11. The method of claim 9, wherein said aligning the wafer to be aligned according to the matching result comprises:
matching the feature images extracted from each of the wafer images with the preset image, respectively;
determining a feature image having a highest matching degree in the wafer images; and
aligning the wafer to be aligned according to the feature image having the highest matching degree.

12. The method of claim 9, wherein said matching the feature images with the preset image comprises:
determining a feature image having a highest matching degree with the preset image in a first wafer image; and
during matching of remaining wafer images, extracting a feature image identical to the feature image having the highest matching degree with the preset image in the first wafer image, and matching the feature image with the preset image.

13. The method of claim 11, wherein feature images extracted from different wafer images are different.

14. The method of claim 1, wherein said matching the plurality of feature images with the preset image comprises:
setting a matching degree score threshold, and
stopping matching of remaining feature images when a matching degree score between a feature image and the preset image reaches the matching degree score threshold.

15. A wafer alignment apparatus, comprising:
a memory for storing a computer program; and
a processor, wherein
the processor is configured to read the computer program stored in the memory to execute the following operations:
obtaining a wafer image of a wafer to be aligned;
extracting a plurality of feature images from the wafer image;
matching the plurality of feature images with a preset image; and
aligning the wafer to be aligned according to the matching result.

16. The wafer alignment apparatus of claim 15, wherein the preset image is unique within a peripheral preset range thereof.

17. The wafer alignment apparatus of claim 15, wherein the preset image is updated in real time according to the wafer to be aligned.

18. The wafer alignment apparatus of claim 15, wherein the processor is further configured to read the computer program stored in the memory to determine a position of the wafer to be aligned according to a feature image having a highest matching degree,
wherein the position of the wafer to be aligned comprises a geometrical relationship of the wafer to be aligned with respect to a stage for placing the wafer to be aligned, and the geometrical relationship comprises at least one of an offset, a rotation angle, or a scale.

19. The wafer alignment apparatus of claim 15, wherein the processor is further configured to read the computer program stored in the memory to:
determine whether a feature image is a unique image in the wafer image; and
if the feature image is the unique image in the wafer image, match the feature image with the preset image.

20. The wafer alignment apparatus of claim 19, wherein if the feature image is not the unique image in the wafer image, the processor is further configured to read the computer program stored in the memory to adjust a size of the wafer image, so that the adjusted feature image is the unique image in the adjusted wafer image.
